(19) United States
(12) Patent Application Publication
(10) Pub. No.: US 2014/0071742 A1
(43) Pub. Date: Mar. 13, 2014

(54) SEMICONDUCTOR MEMORY DEVICE AND METHOD OF OPERATING THE SAME

(71) Applicant: KABUSHIKI KAISHA TOSHIBA, Tokyo (JP)

(72) Inventors: Toshitaka MIYATA, Yokohama-shi (JP); Jyunichi OZEKI, Yokosuka-shi (JP)

(73) Assignee: KABUSHIKI KAISHA TOSHIBA, Tokyo (JP)

(21) Appl. No.: 13/839,194

(22) Filed: Mar. 15, 2013

(30) Foreign Application Priority Data
Sep. 7, 2012 (JP) 2012-197926

(51) Int. Cl. H01L 43/02; G11C 11/16

(52) U.S. Cl. CPC H01L 43/02; G11C 11/161
USPC 365/158; 257/421

(57) ABSTRACT

According to one embodiment, a semiconductor memory device comprises a magnetoresistive element including a memory layer having a variable magnetization direction and made of a material which changes from ferromagnetism to paramagnetism when a voltage is applied, a reference layer having an invariable magnetization direction, and a tunnel barrier layer formed between the memory layer and the reference layer, a first interconnection electrically connected to one terminal of the magnetoresistive element, and a second interconnection electrically connected to the other terminal of the magnetoresistive element, and a third interconnection electrically insulated from the magnetoresistive element.

### CROSS-REFERENCE TO RELATED APPLICATIONS

This application is based upon and claims the benefit of priority from Japanese Patent Application No. 2012-197926, filed Sep. 7, 2012, the entire contents of which are incorporated herein by reference.

### FIELD

Embodiments described herein relate generally to a semiconductor memory device and method of operating the same.

### BACKGROUND

Presently, a dynamic random access memory (DRAM) is widely used as a working memory element forming a large-scale semiconductor integrated circuit. Since the DRAM is volatile, however, stored information is lost when the power supply of the device is turned off. Therefore, a magnetic random access memory (MRAM) as a nonvolatile memory has been researched and developed as a next-generation working memory element.

The MRAM includes a magnetic tunnel junction (MTJ) element using the tunneling magnetoresistive (TMR) effect as a memory element, and stores information in accordance with the magnetized state of this MTJ element. The MTJ element (magnetoresistive element) includes a memory layer having a variable magnetization direction, a reference layer having an invariable magnetization direction, and a tunnel barrier layer formed between them.

A method of writing information in the MTJ element of the MRAM as described above includes spin-transfer torque writing that changes the magnetized state by supplying a spin-polarized current to the MTJ element, and magnetic field writing that changes the magnetized state by applying an external magnetic field to the MTJ element. The spin-transfer torque writing and magnetic field writing pose the following problems.

In spin-transfer torque writing, a current flows directly through the magnetoresistive element. Therefore, it is necessary to sufficiently decrease the thickness of the tunnel barrier layer as an insulating layer. Consequently, the reliability and MR ratio of the magnetoresistive element deteriorate.

In contrast, since an external magnetic field is applied in magnetic field writing, the magnetic field is applied to cells other than a selected cell (selected magnetoresistive element). This may cause a write error. This write error becomes significant as the downsizing (micropatterning) of the cell area advances. The write error can be prevented by increasing the magnetization reversal threshold value. Consequently, however, a large external magnetic field, i.e., a large current is required for magnetization reversal of a selected cell. This poses the problems that the load on a transistor for supplying a current increases and the power increases.

### BRIEF DESCRIPTION OF THE DRAWINGS

FIG. 1 is a circuit diagram showing the structure of a semiconductor memory device according to an embodiment;

FIG. 2 is a sectional view showing the structure of the semiconductor memory device according to the embodiment;

FIG. 3 is a circuit diagram showing an example of an operation of selecting a write target memory cell in a memory cell array according to the embodiment;

FIG. 4 is a view showing an example of a write operation to a memory cell MC according to the embodiment;

FIG. 5 is a view showing another example of the write operation to the memory cell MC according to the embodiment; and

FIGS. 6, 7, 8, 9, and 10 are sectional views showing the manufacturing steps of the semiconductor memory device according to the embodiment.

### DETAILED DESCRIPTION

In general, according to one embodiment, a semiconductor memory device comprises: a magnetoresistive element including a memory layer having a variable magnetization direction and made of a material which changes from ferromagnetism to paramagnetism when a voltage is applied, a reference layer having an invariable magnetization direction, and a tunnel barrier layer formed between the memory layer and the reference layer; a first interconnection electrically connected to one terminal of the magnetoresistive element, and a second interconnection electrically connected to the other terminal of the magnetoresistive element; and a third interconnection electrically insulated from the magnetoresistive element.

This embodiment will be explained below with reference to the accompanying drawing. In the drawing, the same reference numerals denote the same parts. Also, a repetitive explanation will be made as needed.

### EMBODIMENT

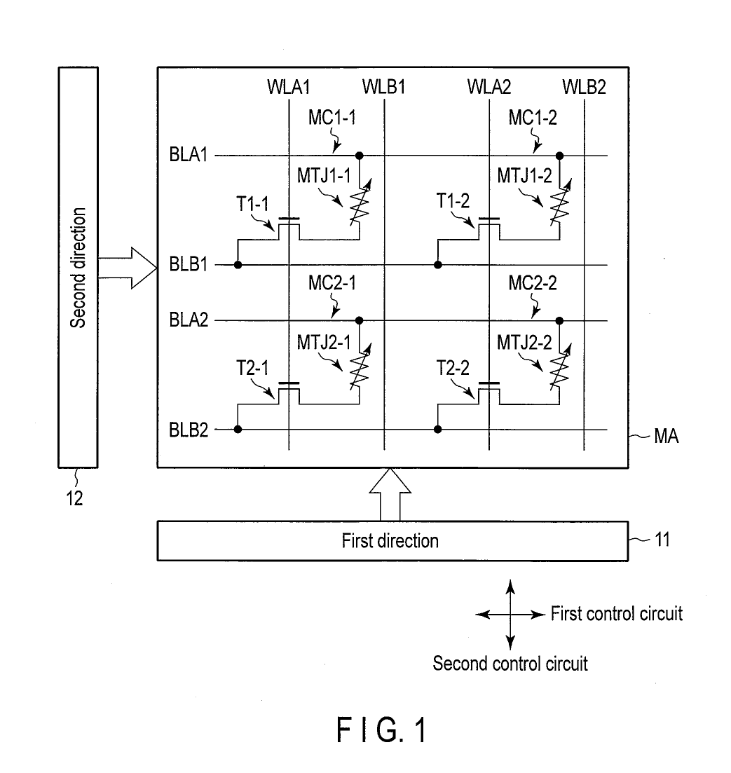

The semiconductor memory device according to this embodiment will be explained below with reference to FIGS. 1, 2, 3, 4, 5, 6, 7, 8, 9, and 10. An MRAM of this embodiment is an example in which the magnetization reversal threshold value is decreased by applying a voltage to a memory layer 31 of a magnetoresistive element MTJ, and data is rewritten by the magnetic field writing method in this state. This makes it possible to reduce the write current and the area. This embodiment will be explained in detail below.

### [Structure]

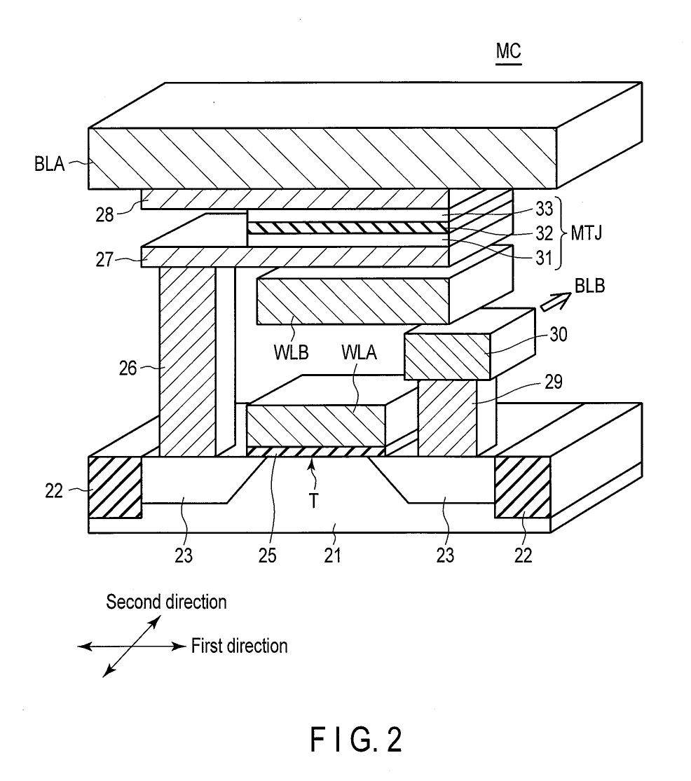

The structure of the semiconductor memory device according to this embodiment will be explained below with reference to FIGS. 1 and 2.

FIG. 1 is a circuit diagram showing the structure of the semiconductor memory device according to this embodiment.

As shown in FIG. 1, memory cells MC1-1, MC1-2, MC2-1, and MC2-2 are arranged in a matrix in a memory cell array MA. Memory cell MC1-1 includes a series circuit of a magnetoresistive element MTJ1-1 and a switching element (for example, FET) T1-1. Similarly, memory cell MC1-2 includes a series circuit of a magnetoresistive element MTJ1-2 and switching element T1-2, memory cell MC2-1 includes a series circuit of a magnetoresistive element MTJ2-1 and switching element T2-1, and memory cell MC2-2 includes a series circuit of a magnetoresistive element MTJ2-2 and switching element T2-2.

One terminal of the series circuit of each of memory cells MC1-1 and MC1-2 (i.e., one terminal of each of magnetoresistive elements MTJ1-1 and MTJ1-2) is connected a bit line BLA1, and the other terminal of each series circuit (i.e., one terminal of each of switching elements T1-1 and T1-2) is connected to a bit line BLB1. In contrast, one terminal of the series circuit of each of memory cells MC2-1 and MC2-2 (i.e., one terminal of each of magnetoresistive elements MTJ2-1 and MTJ2-2) is connected a bit line BLA2, and the other terminal of each series circuit (i.e., one terminal of each of switching elements T2-1 and T2-2) is connected to a bit line BLB2.

A voltage can be applied to magnetoresistive elements MTJ1-1 and MTJ1-2 by producing a potential difference between bit lines BLA1 and BLB1. Also, a voltage can be applied to magnetoresistive elements MTJ2-1 and MTJ2-2 by producing a potential difference between bit lines BLA2 and BLB2.

The control terminals of switching elements T1-1 and T2-1, for example, the gate electrodes of the FETs are connected together to a word line WLA1. The control terminals of switching elements T1-2 and T2-2 are connected together to a word line WLA2.

A word line WLB1 isolated from magnetoresistive elements MTJ1-1 and MTJ2-1 runs near them. A current can flow bidirectionally through word line WLB1, and word line WLB1 generates a magnetic field around it in accordance with the current. This magnetic field is applied as a write field to magnetoresistive elements MTJ1-1 and MTJ2-1. Likewise, a word line WLB2 isolated from magnetoresistive elements MTJ1-2 and MTJ2-2 runs near them. A current can flow bidirectionally through word line WLB2, and word line WLB2 generates a magnetic field around it in accordance with the current. This magnetic field is applied as a write field to magnetoresistive elements MTJ1-2 and MTJ2-2.

Bit lines BLA1, BLA2, BLB1, and BLB2 run in a first direction. Word lines WLA1, WLA2, WLB1, and WLB2 run in a second direction perpendicular to the first direction. A first control circuit 11 controls the potentials of word lines WLA1, WLA2, WLB1, and WLB2. A second control circuit 12 controls the potentials of bit lines BLA1, BLA2, BLB1, and BLB2.

FIG. 2 is a perspective view showing the structure of the semiconductor memory device according to this embodiment. FIG. 2 shows one memory cell MC shown in FIG. 1.

As shown in FIG. 2, the memory cell MC includes a switching element T and the magnetoresistive element MTJ formed on a semiconductor substrate 21.

The semiconductor substrate 21 is, for example, a silicon substrate, and its conductivity type can be either a p- or n-type. In the semiconductor substrate 21, an SiO₂ layer having an STI structure, for example, is formed as an element isolation insulating layer 22.

The switching element T is formed in the surface region of the semiconductor substrate 21, more specifically, in an element region (active area) surrounded by the element isolation insulating layer 22. In this example, the switching element T is FET, and includes two source/drain diffusion layers 23 in the semiconductor substrate 21, and a gate insulating film 25 and gate electrode formed on a channel region between the source/drain diffusion layers 23. The gate electrode extends in the second direction, and functions as a word line WLA. The switching element T is covered with an interlayer dielectric layer (for example, SiO₂) (not shown).

Contact holes are formed in the interlayer dielectric layer, and contact plugs 26 and 29 are formed in these contact holes.

The lower surface of the contact plug 29 is connected to the switching element T. In this example, the contact plug 29 is in direct contact with, for example, the source side of the source/drain diffusion layers 23. The contact plug 29 is made of a metal material such as W or Cu.

An interconnection 30 made of, for example, Cu or Al is formed on the contact plug 29. The interconnection 30 is electrically connected to a bit line BLB (not shown in FIG. 2).

The lower surface of the contact plug 26 is connected to the switching element T. In this example, the contact plug 26 is in direct contact with, for example, the drain side of the source/drain diffusion layers 23. The contact plug 26 is made of a metal material such as W or Cu.

A lower electrode 27 is formed on the contact plug 26. The lower surface of the end portion of the lower electrode 27 is in contact with the contact plug 26, and the lower electrode 27 extends in, for example, the first direction. The lower electrode 27 has a multilayered structure including, for example, Ta (10 nm) /Ru (5 nm) /Ta (5 nm).

The magnetoresistive element MTJ is formed on the lower electrode 27. The magnetoresistive element MTJ is not positioned immediately above the contact plug 26, and does not overlap the contact plug 26. The magnetoresistive element MTJ includes the memory layer 31, a tunnel barrier layer 32, and a reference layer 33.

The memory layer 31 is formed on the lower electrode 27. The memory layer 31 is a ferromagnetic layer having a variable magnetization direction, and has in-plane magnetization parallel or almost parallel to the film surfaces (upper surface/lower surface). “Variable magnetization direction” herein mentioned means that the magnetization direction varies with respect to a predetermined write current. Also, “almost parallel” means that the direction of residual magnetization falls within the range of 0°≦θ≦45° with respect to the film surfaces.

The memory layer 31 is made of a material that changes from a ferromagnetic material to a paramagnetic material when a voltage is applied. Also, the material forming the memory layer 31 changes from the paramagnetic material to the ferromagnetic material when the applied voltage is set to zero. “Paramagnetic” herein mentioned means the property that the material is magnetized in the same direction as that of an applied magnetic field, and the influence of magnetization disappears when the magnetic field is set to zero. Also, “ferromagnetic” means the property that the material is magnetized in the same direction as that of an applied magnetic field, and the influence of magnetization remains even when the magnetic field is set to zero.

In other words, the material that changes from the ferromagnetic material to the paramagnetic material when a voltage is applied is a material that decreases the Curie temperature when a voltage is applied. As will be described in detail later, the magnetization reversal threshold value (coercive force) can be decreased by the change from the ferromagnetic material to the paramagnetic material.

The memory layer 31 is made of Pt and Co as materials as described above. More specifically, the memory layer 31 is, for example, a multilayered film including a Pt layer and Co layer. This multilayered film can be formed by stacking one Pt layer and one Co layer, and can also be formed by alternately stacking a plurality of Pt layers and a plurality of Co layers.

In this multilayered film, the film thickness of the Pt layer is, for example, about 1.0 nm, and that of the Co layer is, for example, about 0.4 nm.

Note that the materials forming the memory layer 31 are not limited to Pt and Co. The memory layer 31 may also be formed by, for example, Pt and Pd. It is also possible to form the memory layer 31 by using at least one of, for example, Co, Fe, Ni, and an alloy containing two or more of these elements. More specifically, the memory layer 31 is formed by a multilayered film of a Pt layer and Pd layer. It is also possible to form the memory layer 31 by using any of a Co layer, Fe layer, Ni layer, and alloy layer, or a multilayered film including two or more of these layers.

The tunnel barrier layer 32 is formed on the memory layer 31. The tunnel barrier layer 32 is a nonmagnetic layer, and made of, for example, MgO or Al₂O₃. The film thickness of the tunnel barrier layer 32 is, for example, about 2.0 nm.

The reference layer 33 is formed on the tunnel barrier layer 32. The reference layer 33 is a ferromagnetic layer having an invariable magnetization direction, and has in-plane magnetization parallel or almost parallel to the film surfaces. “Invariable magnetization direction” herein mentioned means that the magnetization direction remains unchanged with respect to a predetermined write current. That is, the magnetization reversal threshold value in the magnetization direction of the reference layer 33 is larger than that of the memory layer 31. The reference layer 33 is made of, for example, Fe, Co, Ni, or an alloy containing two or more of these elements. The reference layer 33 need only have an invariable magnetization direction, and its film thickness is appropriately adjusted.

An upper electrode 28 (for example, W) is formed on the magnetoresistive element MTJ, and the magnetoresistive element MTJ is connected to a bit line (for example, Cu) BLA running in the first direction through the upper electrode 28.

As described above, the magnetoresistive element MTJ has one terminal connected to bit line BLA, and the other terminal connected to bit line BLB. In other words, the magnetoresistive element MTJ is formed between bit lines BLA and BLB. Therefore, a voltage can be applied to the magnetoresistive element MTJ by producing a potential difference between bit lines BLA and BLB.

A magnetic field writing word line WLB running in the second direction is formed below the magnetoresistive element MTJ (i.e., below the lower electrode 27). Word line WLB is formed to overlap at least a portion of the magnetoresistive element MTJ, and isolated from it. Also, word line WLB is formed at a short distance from the magnetoresistive element MTJ, so that word line WLB can apply a magnetic field to the memory layer 31 of the magnetoresistive element MTJ. Accordingly, a magnetic field can be applied to the magnetoresistive element MTJ by supplying a current to word line WLB. More specifically, word line WLB applies a magnetic field so as to magnetize the memory layer 31 in the in-plane direction. Word line WLB is made of a metal material such as Cu or Al, but the material is not limited to this.

Note that the positions of the memory layer 31 and reference layer 33 may also be switched. That is, the reference layer 33, tunnel barrier layer 32, and memory layer 31 can be formed in this order on the lower electrode 27.

Note also that the planar shape of the magnetoresistive element MTJ is a rectangle in FIG. 2, but the planar shape is not limited to this. For example, the planar shape of the magnetoresistive element MTJ can also be a square, circle, or ellipse.

Furthermore, the memory layer 31 and reference layer 33 may also have perpendicular magnetization that is perpendicular or almost perpendicular to the film surfaces. “Almost perpendicular” herein mentioned means that the direction of residual magnetization falls within the range of 45°≦θ≦90°.

In this case, word line WLB is not formed below the magnetoresistive element MTJ, but formed on its side. In other words, word line WLB is formed in the same layer as that of the magnetoresistive element MTJ (the memory layer 31). Accordingly, word line WLB applies a magnetic field so as to magnetize the memory layer 31 in the perpendicular direction.

When the memory layer 31 and reference layer 33 have perpendicular magnetization, the influence of a leakage magnetic field from the reference layer 33 to the memory layer 31 is larger than that when the memory layer 31 and reference layer 33 have in-plane magnetization. In this embodiment, after the magnetization reversal threshold value of the memory layer 31 is decreased, the magnetization direction in the memory layer 31 is set by applying an external magnetic field, as will be described in detail later. When the reference layer 33 has perpendicular magnetization, therefore, the leakage magnetic field from the reference layer 33 exerts an influence on the memory layer 31 after the magnetization reversal threshold value of the memory layer 31 is decreased.

Accordingly, when giving perpendicular magnetization to the memory layer 31 and reference layer 33, a shift adjustment layer is desirably formed above (or below) the reference layer 33 with a spacer layer (for example, Ru) (not shown) being sandwiched between them. The shift adjustment layer is a magnetic layer having an invariable magnetization direction, and this magnetization direction is opposite to that of the reference layer 33. Therefore, the shift adjustment layer can cancel the leakage magnetic field from the reference layer 33 to the memory layer 31. This shift adjustment layer is made of, for example, an artificial lattice having a multilayered structure containing a magnetic material such as Ni, Fe, or Co and a nonmagnetic material such as Cu, Pd, or Pt.

### [Operation Example]

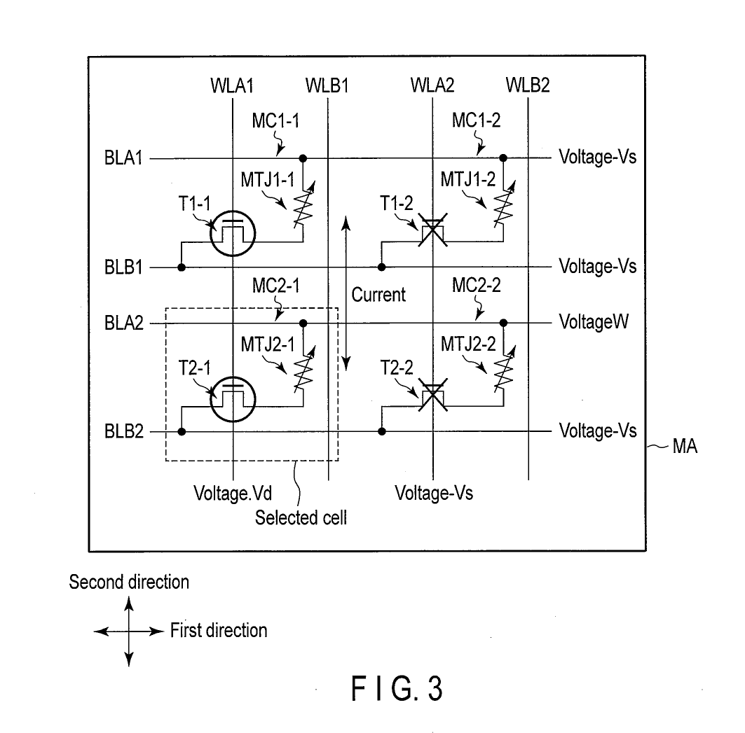

An operation example of the semiconductor memory device according to this embodiment will be explained below with reference to FIGS. 3, 4, and 5.

First, a method of selecting the memory cell MC as a write target in the memory cell array MA will be explained.

FIG. 3 is a circuit diagram showing an example of the operation of selecting the memory cell MC as a write target in the memory cell array MA according to this embodiment. Assume that memory cell MC2-1 is a selected cell as a write target.

As shown in FIG. 3, a voltage −Vs (Vs>0) is applied to bit line BLB2 connected to the other terminal of the series circuit (the source of switching element T2-1) of memory cell MC2-1 as a selected cell. Also, a voltage W (W>0) is applied to bit line BLA2 connected to one terminal of the series circuit (one terminal of magnetoresistive element MTJ2-1) of memory cell MC2-1. In addition, a voltage Vd at which switching element T2-1 is sufficiently turned on is applied to the gate of switching element T2-1, i.e., to word line WLA1. This produces a potential difference between bit lines BLA2 and BLB2. Consequently, a voltage W+Vs is applied to magnetoresistive element MTJ2-1.

In contrast, voltage -Vs is applied to bit line BLB1 connected to the other terminal of the series circuit (the source of switching element T1-1) of memory cell MC1-1 as an unselected cell. Also, voltage −Vs is applied to bit line BLA1 connected to one terminal of the series circuit (one terminal of magnetoresistive element MTJ1-1) of memory cell MC1-1. In addition, since the gate of switching element T1-1 is connected to that of switching element T2-1 (word line WLA1), voltage Vd at which switching element T1-1 is sufficiently turned on is applied to the gate of switching element T1-1. In this state, bit lines BLA1 and BLB1 are at the same potential, and no potential difference is produced between them. Consequently, no voltage is applied to magnetoresistive element MTJ1-1. Voltage -Vs is applied to bit line BLB1 connected to the other terminal of the series circuit (the source of switching element T1-2) of memory cell MC1-2 as an unselected cell. Also, voltage −Vs is applied to bit line BLA1 connected to one terminal of the series circuit (one terminal of magnetoresistive element MTJ1-2) of memory cell MC1-2. In addition, voltage −Vs at which switching element T1-2 is turned off is applied to the gate of switching element T1-2, i.e., to word line WLA2. In this state, bit lines BLA1 and BLB1 are at the same potential, and no potential difference is produced between them. Also, switching element T1-2 is turned off. Consequently, no voltage is applied to magnetoresistive element MTJ1-1.

Voltage -Vs is applied to bit line BLB2 connected to the other terminal of the series circuit (the source of switching element T2-2) of memory cell MC2-2 as an unselected cell. Also, voltage W is applied to bit line BLA2 connected to one terminal of the series circuit (one terminal of magnetoresistive element MTJ2-2) of memory cell MC2-2. In addition, since the gate of switching element T2-2 is connected to that of switching element T1-2 (word line WLA2), voltage −Vs at which switching element T2-2 is turned off is applied to the gate of switching element T2-2. In this state, a potential difference is produced between bit lines BLA2 and BLB2. However, switching element T2-2 is turned off. Therefore, no voltage is applied to magnetoresistive element MTJ2-2, or a voltage equal to or lower than voltage W is applied to it.

As described above, voltage W+Vs can be applied to selected magnetoresistive element MTJ2-1 by producing a potential difference between bit lines BLA and BLB connected to memory cell MC2-1 as a selected cell and turning on switching element T2-1 positioned between them.

In this state, a ferromagnetism/paramagnetism transition threshold voltage Vth of the memory layer 31 in each of magnetoresistive elements MTJ1-1, MTJ1-2, MTJ2-1, and MTJ2-2 is set such that W<Vth<W+Vs. Consequently, only the memory layer 31 of selected memory cell MC2-1 to which voltage W+Vs is applied can change to paramagnetism. That is, it is possible to selectively decrease only the magnetization reversal threshold value of the memory layer 31 of magnetoresistive element MTJ2-1. In this state, magnetoresistive element MTJ2-1 can be programmed with a low current by applying a magnetic field to magnetoresistive element MTJ2-1 by supplying a current to word line WLA1 close to magnetoresistive element MTJ2-1.

Next, a practical data programming method for the selected memory cell MC will be explained.

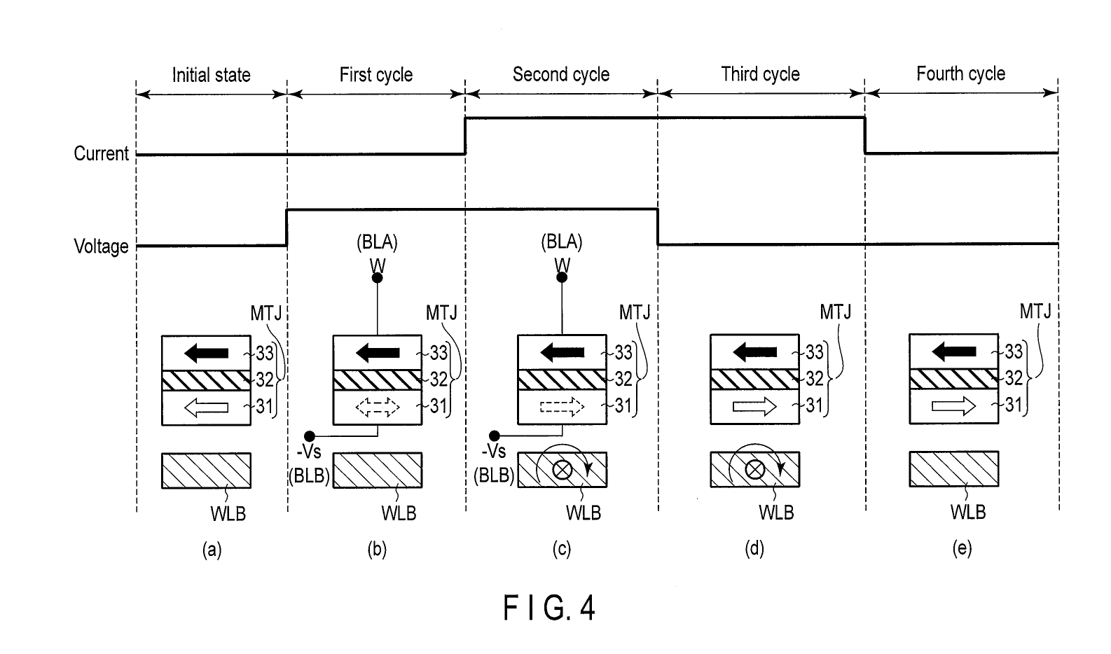

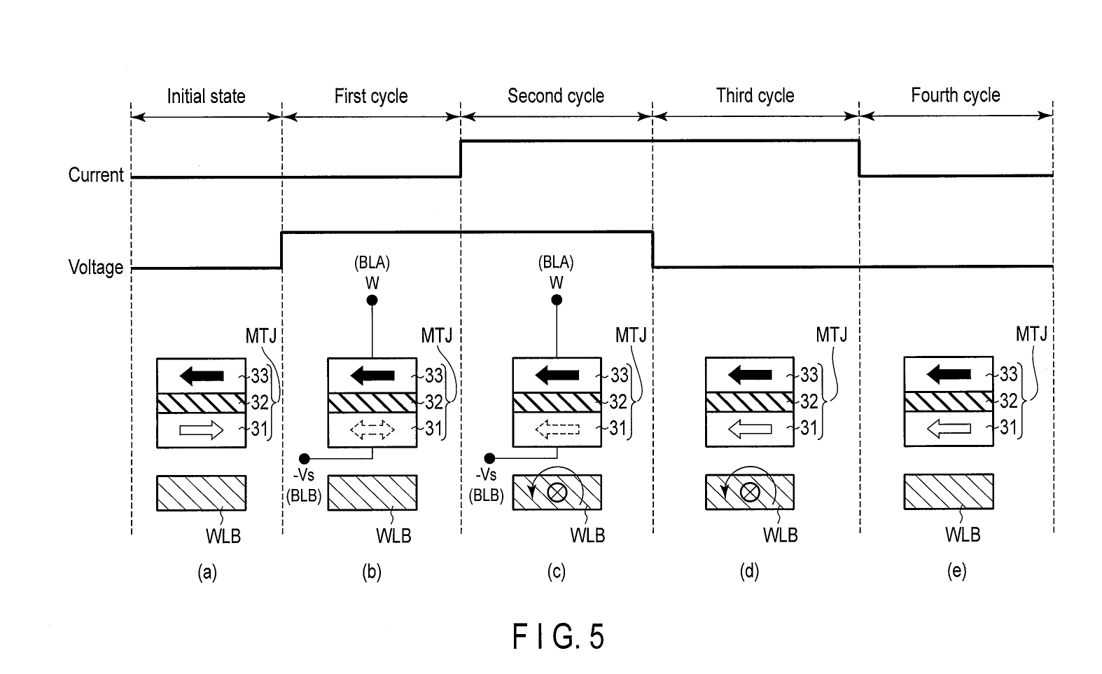

FIG. 4 is a view showing an example of the write operation to the memory cell MC according to this embodiment. FIG. 5 is a view showing another example of the write operation to the memory cell MC according to this embodiment. More specifically, FIG. 4 shows the write operation from binary 0 to binary 1, and FIG. 5 shows the write operation from binary 1 to binary 0. Note that FIGS. 4 and 5 particularly show the sectional views of the magnetoresistive element MTJ and word line WLB, a voltage to be applied to the magnetoresistive element MTJ, and a current that flows through word line WLB.

First, the write operation from binary 0 to binary 1 will be explained with reference to FIG. 4.

In the initial state as indicated by (a) in FIG. 4, the magnetization direction in the memory layer 31 is the same as that in the reference layer 33. In other words, the magnetization directions in the memory layer 31 and reference layer 33 are set in a parallel arrangement. In this parallel arrangement, the resistance of the magnetoresistive element MTJ is smallest. This state is defined as, for example, binary 0. In this initial state, no voltage is applied to the magnetoresistive element MTJ, and no current flows through word line WLB.

Then, in the first cycle as indicated by (b) in FIG. 4, a voltage is applied to the magnetoresistive element MTJ without supplying a current to word line WLB. More specifically, voltage W is applied to bit line BLA connected to one terminal of the magnetoresistive element MTJ, and voltage −Vs is applied to bit line BLB connected to the other terminal. Consequently, a potential difference is produced between bit lines BLA and BLB, and voltage W+Vs is applied to the magnetoresistive element MTJ positioned between them. Voltage W+Vs is, for example, 1.0 to 1.5 V. This changes the memory layer 31 from ferromagnetism to paramagnetism. In other words, magnetization in the memory layer 31 is destroyed, so the magnetization reversal threshold value of the memory layer 31 decreases (to almost zero).

Note that the voltage to be applied to the magnetoresistive element MTJ is not limited to the above-mentioned range. The voltage to be applied to the magnetoresistive element MTJ need only be high to such an extent that the memory layer 31 changes from a ferromagnetic material to a paramagnetic material. Note also that the voltage is desirably low to such an extent that no current flows through the magnetoresistive element MTJ, but a current may also flow through it.

Subsequently, in the second cycle as indicated by (c) in FIG. 4, a current flows through word line WLB while the voltage is kept applied to the magnetoresistive element MTJ. Consequently, a magnetic field is generated around word line WLB, and applied to the magnetoresistive element MTJ. In this state, the current flows through word line WLB so as to generate a magnetic field with which the magnetization direction in the memory layer 31 becomes opposite to that in the reference layer 33. Referring to (c) in FIG. 4, the current flows backward on the drawing surface through word line WLB. Consequently, the magnetization directions in the memory layer 31 and reference layer 33 are set in an antiparallel arrangement.

In this state, the magnetization reversal threshold value of the magnetoresistive element MTJ (the memory layer 31) is small because the voltage is applied to it. Therefore, even when the magnetic field generated from word line WLB is small, the magnetization direction in the memory layer 31 can be reversed. That is, the current flowing through word line WLB can be decreased. This current is, for example, about a few tens of microamps.

Also, the memory layer 31 is paramagnetic because the voltage is applied to the magnetoresistive element MTJ. Accordingly, while the magnetic field is applied from word line WLB to the memory layer 31, the memory layer 31 is magnetized in the direction opposite to the magnetization direction in the reference layer 33, but the magnetization reversal threshold value is small and unstable.

In the third cycle as indicated by (d) in FIG. 4, while the current is flowing through word line WLB, the application of the voltage to the magnetoresistive element MTJ is stopped. More specifically, bit lines BLA and BLB are set at the same potential (for example, voltage −Vs). This changes the memory layer 31 from paramagnetism to ferromagnetism. Accordingly, the magnetization reversal threshold value of the memory layer 31 increases while the magnetization directions in the memory layer 31 and reference layer 33 are kept in the antiparallel arrangement. In this antiparallel arrangement, the resistance of the magnetoresistive element MTJ is largest. This state is defined as, for example, binary 1.

After that, in the fourth cycle as indicated by (e) in FIG. 4, the current flowing through word line WLB is stopped. Consequently, word line WLB generates no magnetic field, so no magnetic field is applied to the magnetoresistive element MTJ any longer. Since the memory layer 31 is ferromagnetic in this state, the magnetization direction remains unchanged even when the application of the magnetic field is stopped, so the antiparallel arrangement in the magnetoresistive element MTJ is maintained.

Thus, the write of binary 1 in this embodiment is complete.

The write operation from binary 1 to binary 0 will now be explained with reference to FIG. 5.

In the initial state as indicated by (a) in FIG. 5, the magnetization direction in the memory layer 31 is opposite to that in the reference layer 33. In other words, the magnetization directions in the memory layer 31 and reference layer 33 are set in the antiparallel arrangement. In this initial state, no voltage is applied to the magnetoresistive element MTJ, and no current flows through word line WLB.

Then, in the first cycle as indicated by (b) in FIG. 5, a voltage is applied to the magnetoresistive element MTJ without supplying a current to word line WLB. More specifically, voltage W is applied to bit line BLA connected to one terminal of the magnetoresistive element MTJ, and voltage −Vs is applied to bit line BLB connected to the other terminal. Consequently, a potential difference is produced between bit lines BLA and BLB, and voltage W+Vs is applied to the magnetoresistive element MTJ positioned between them. Voltage W+Vs is, for example, 1.0 to 1.5 V. This changes the memory layer 31 from ferromagnetism to paramagnetism. In other words, magnetization in the memory layer 31 is destroyed, so the magnetization reversal threshold value of the memory layer 31 decreases (to almost zero).

Note that the voltage to be applied to the magnetoresistive element MTJ is not limited to the above-mentioned range. The voltage to be applied to the magnetoresistive element MTJ need only be high to such an extent that the memory layer 31 changes from ferromagnetism to paramagnetism. Note also that the voltage is desirably low to such an extent that no current flows through the magnetoresistive element MTJ, but a current may also flow through it.

Subsequently, in the second cycle as indicated by (c) in FIG. 5, a current flows through word line WLB while the voltage is kept applied to the magnetoresistive element MTJ. Consequently, a magnetic field is generated around word line WLB, and applied to the magnetoresistive element MTJ. In this state, the current flows through word line WLB so as to generate a magnetic field with which the magnetization direction in the memory layer 31 becomes the same as that in the reference layer 33. Referring to (c) in FIG. 5, the current flows forward on the drawing surface through word line WLB. Consequently, the magnetization directions in the memory layer 31 and reference layer 33 are set in the parallel arrangement.

In this state, the magnetization reversal threshold value of the magnetoresistive element MTJ (the memory layer 31) is small because the voltage is applied to it. Therefore, even when the magnetic field generated from word line WLB is small, the magnetization direction in the memory layer 31 can be reversed. That is, the current flowing through word line WLB can be decreased. This electric current is, for example, about a few tens of microamps.

Also, the memory layer 31 is paramagnetic because the voltage is applied to the magnetoresistive element MTJ. Accordingly, while the magnetic field is applied from word line WLB to the memory layer 31, the memory layer 31 is magnetized in the same direction as the magnetization direction in the reference layer 33, but the magnetization reversal threshold value is small and unstable.

In the third cycle as indicated by (d) in FIG. 5, while the current is flowing through word line WLB, the application of the voltage to the magnetoresistive element MTJ is stopped. More specifically, bit lines BLA and BLB are set at the same potential (for example, voltage −Vs). This changes the memory layer 31 from paramagnetism to ferromagnetism. Accordingly, the magnetization reversal threshold value of the memory layer 31 increases while the magnetization directions in the memory layer 31 and reference layer 33 are kept in the parallel arrangement.

After that, in the fourth cycle as indicated by (e) in FIG. 5, the current flowing through word line WLB is stopped. Consequently, word line WLB generates no magnetic field, so no magnetic field is applied to the magnetoresistive element MTJ any longer. Since the memory layer 31 is ferromagnetic in this state, the magnetization direction remains unchanged even when the application of the magnetic field is stopped, so the parallel arrangement in the magnetoresistive element MTJ is maintained.

Thus, the write of binary 0 in this embodiment is complete.

Note that in the binary 1 write and binary 0 write, the application start and stop timings of the voltage and magnetic field are not limited to those of the operations shown in FIGS. 4 and 5. That is, the stop of the application of the magnetic field need only be after the stop of the application of the voltage.

For example, the application of the magnetic field can be started before or simultaneously with the start of the application of the voltage, or after the stop of the application of the voltage.

Next, a read operation of the memory cell MC will be explained.

In the read operation, voltages are appropriately applied to bit line BLA and word line WLA, and a read current flows through the magnetoresistive element MTJ. This read current is set at a value at which the magnetization direction in the memory layer 31 does not reverse. Data can be read out by detecting the change in resistance of the magnetoresistive element MTJ (i.e., the change in the tunnel current flowing through the switching element T) in this state.

### [Manufacturing Method]

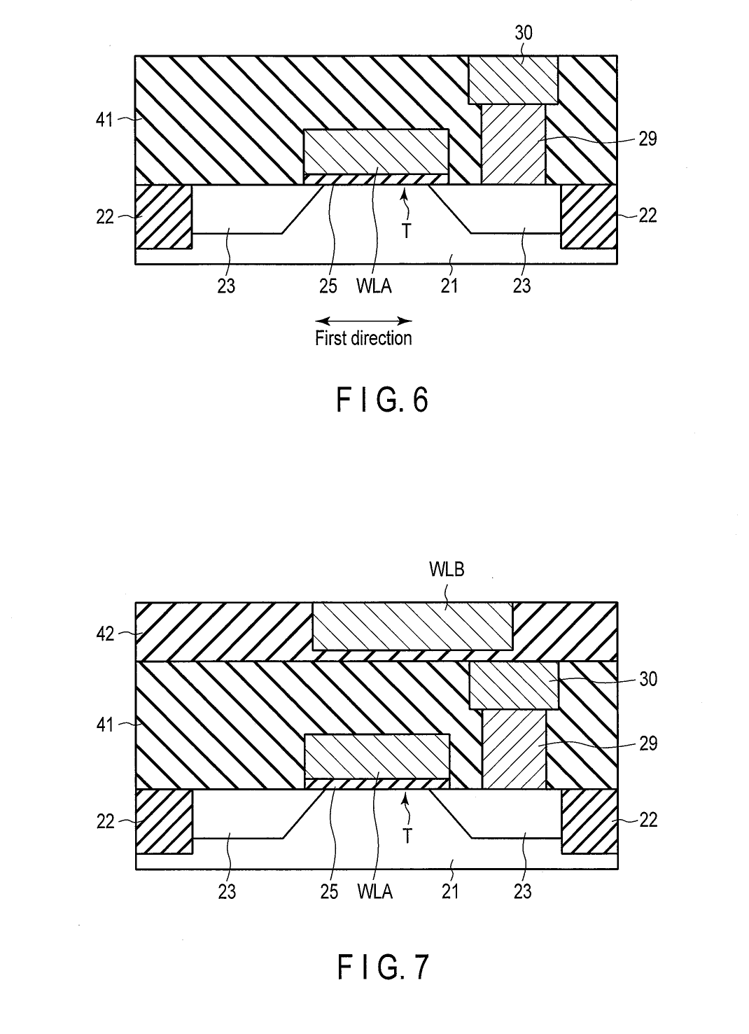

A method of manufacturing the semiconductor memory device according to this embodiment will be explained below with reference to FIGS. 6, 7, 8, 9, and 10. FIGS. 6, 7, 8, 9, and 10 are sectional views showing the manufacturing steps of the semiconductor memory device according to this embodiment.

First, an STI structure is formed as an element isolation insulating layer 22 in a semiconductor substrate 21. After that, a switching element T as an

FET is formed in the surface region of the semiconductor substrate 21, more specifically, in an element region (active area) surrounded by the element isolation insulating layer 22. The switching element T is formed by forming a gate insulating film 25 and a gate electrode (word line WLA) on the semiconductor substrate 21 by, for example, chemical vapor deposition (CVD), processing these components into a desired shape by, for example, reactive ion etching (RIE), and forming two source/drain diffusion layers 23 in the semiconductor substrate 21.

Then, an interlayer dielectric layer 41 is formed to cover the entire surface by, for example, CVD. Subsequently, a contact hole and interconnection trench are formed in the interlayer dielectric layer 41 so as to expose the surface of the source side of the source/drain diffusion layers 23. After that, a contact plug 29 and interconnection 30 are formed by burying a metal material in the contact hole and interconnection trench. The contact plug 29 is in direct contact with the surface of the source side of the source/drain diffusion layers 23, and the interconnection 30 is electrically connected to a bit line BLB. Note that an example using a so-called damascene method is explained in this embodiment, but this embodiment is not limited to this method.

As shown in FIG. 7, an interlayer dielectric layer 42 is formed on the interlayer dielectric layer 41 and interconnection 30 by, for example, CVD. After that, an interconnection trench is formed in the interlayer dielectric layer 42, and a word line WLB is formed by burying a metal material such as Cu or Al in this interconnection trench.

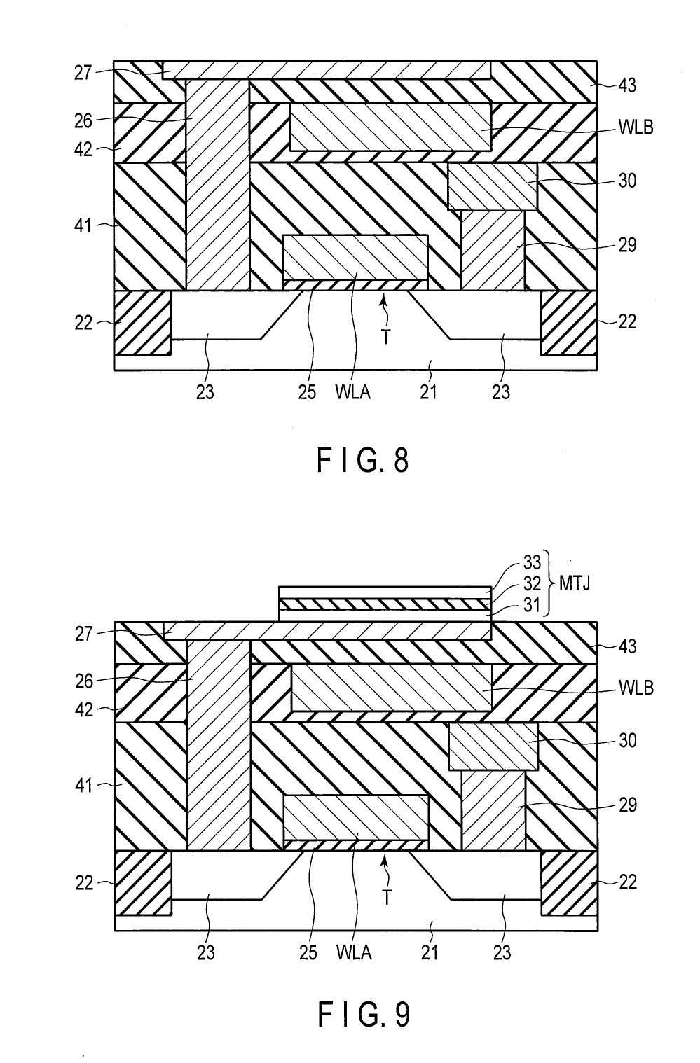

As shown in FIG. 8, an interlayer dielectric layer 43 is formed on the interlayer dielectric layer 42 and word line WLB by, for example, CVD. Then, a contact hole is formed through the interlayer dielectric layers 41, 42, and 43 so as to expose the surface of the drain side of the source/drain diffusion layers 23. After that, a contact plug 26 is formed by burying a metal material in the contact hole. The contact plug 26 is in direct contact with the surface of the drain side of the source/drain diffusion layers 23. After that, a lower electrode 27 is formed on the contact plug 26, and processed into a desired shape.

As shown in FIG. 9, a memory layer 31, tunnel barrier layer 32, and reference layer 33 are sequentially formed on the entire surface by, for example, CVD. After that, the reference layer 33, tunnel barrier layer 32, and memory layer 31 are processed into a desired shape by, for example, RIE, thereby forming a magnetoresistive element MTJ. In this state, the magnetoresistive element MTJ is electrically connected to the lower electrode 27. Also, the magnetoresistive element MTJ is formed to be positioned above word line WLB.

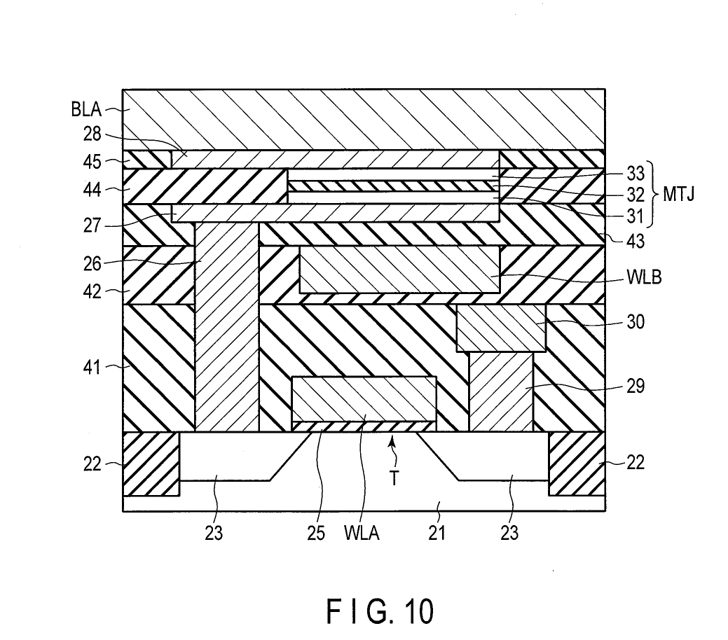

As shown in FIG. 10, an interlayer dielectric layer 44 is formed on the entire surface by, for example, CVD. After that, the upper surface is planarized by, for example, chemical mechanical polishing (CMP). This exposes the upper surface of the magnetoresistive element MTJ (i.e., the upper surface of the reference layer 33).

Then, an upper electrode 28 is formed on the magnetoresistive element MTJ and interlayer dielectric layer 44, and processed into a desired shape. In this state, the upper electrode 28 is electrically connected to the magnetoresistive element MTJ. Subsequently, an interlayer dielectric layer 45 is formed on the entire surface by, for example, CVD. After that, the upper surface is planarized by, for example, CMP. This exposes the upper surface of the upper electrode 28.

After that, an interlayer dielectric layer (not shown) is formed on the upper electrode 28 and interlayer dielectric layer 45 by, for example, CVD, and an interconnection trench is formed in this interlayer dielectric layer so as to expose the upper surface of the upper electrode 28. Then, a bit line BLA is formed by burying a metal material such as Cu or Al in the interconnection trench. In this state, bit line BLA is in contact with and electrically connected to the upper electrode 28.

The semiconductor memory device according to this embodiment is thus formed.

### [Effects]

In the above-mentioned embodiment, the MRAM uses the magnetic field writing method, and includes bit line BLA connected to one terminal of the magnetoresistive element MTJ, bit line BLB connected to the other terminal of the magnetoresistive element MTJ, and word line WLB isolated from the magnetoresistive element MTJ. A voltage is applied to the magnetoresistive element MTJ by producing a potential difference between bit lines BLA and BLB, thereby decreasing the magnetization reversal threshold value of the memory layer 31. After that, while the magnetization reversal threshold value of the memory layer 31 is kept small, a magnetic field writing operation is performed by applying a magnetic field from word line WLB to the memory layer 31. Consequently, a write current to be supplied to word line WLB in the magnetic field writing can be reduced.

Also, the magnetic field to be generated from word line WLB can be decreased by decreasing the write current. This makes it possible to decrease the influence of a magnetic field to be applied to peripheral memory cells other than a selected memory cell, and prevent a write error. Accordingly, scaling can be performed while preventing a write error, so it is possible to reduce (downsize) the inter-cell distance, i.e., the area of the memory cell array MA.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a magnetoresistive element including a memory layer having a variable magnetization direction and made of a material which changes from ferromagnetism to paramagnetism when a voltage is applied, a reference layer having an invariable magnetization direction, and a tunnel barrier layer formed between the memory layer and the reference layer;
a first interconnection electrically connected to one terminal of the magnetoresistive element, and a second interconnection electrically connected to the other terminal of the magnetoresistive element; and
a third interconnection electrically insulated from the magnetoresistive element.

2. The device of claim 1, wherein
a voltage is applied to the memory layer by a potential difference produced between the first interconnection and the second interconnection, and
a magnetic field is applied to the memory layer by supplying a current to the third interconnection, and data is written in the magnetoresistive element.

3. The device of claim 1, wherein the memory layer contains Pt and Co.

4. The device of claim 1, wherein the memory layer comprises a multilayered film including a Pt layer and a Co layer, and a film thickness of the Pt layer is larger than that of the Co layer.

5. The device of claim 1, wherein the memory layer and the reference layer have in-plane magnetization.

6. The device of claim 1, wherein the memory layer contains Pt and Pd.

7. The device of claim 1, wherein the memory layer contains at least one of Co, Fe, Ni, and an alloy containing not less than two of Co, Fe, and Ni.

8. The device of claim 1, wherein
the memory layer and the reference layer have perpendicular magnetization, and
the magnetoresistive element further includes a shift adjustment layer having an invariable magnetization direction opposite to the magnetization direction in the reference layer.

9. The device of claim 1, wherein the magnetoresistive element and the second interconnection are electrically connected via a current path of a transistor.

10. The device of claim 1, wherein the reference layer contains one of Co, Fe, Ni, and alloys of Co, Fe, and Ni.

11. The device of claim 1, wherein the tunnel barrier layer contains one of MgO and Al₂O₃.

12. A method of operating a semiconductor memory device comprising:
a magnetoresistive element including a memory layer having a variable magnetization direction and made of a material which changes from ferromagnetism to paramagnetism when a voltage is applied, a reference layer having an invariable magnetization direction, and a tunnel barrier layer formed between the memory layer and the reference layer;
a first interconnection electrically connected to one terminal of the magnetoresistive element, and a second interconnection electrically connected to the other terminal of the magnetoresistive element; and
a third interconnection electrically insulated from the magnetoresistive element, the method comprising:
when writing data in the magnetoresistive element,
applying a voltage to the memory layer by producing a potential difference between the first interconnection and the second interconnection; and
applying a magnetic field to the memory layer by supplying a current to the third interconnection.

13. The method of claim 12, wherein the voltage to be applied to the memory layer is 1.0 to 1.5 V.

14. The method of claim 12, wherein the memory layer contains Pt and Co.

15. The method of claim 12, wherein the memory layer comprises a Pt layer and a Co layer, and a film thickness of the Pt layer is larger than that of the Co layer.

16. The method of claim 12, wherein the memory layer contains Pt and Pd.

17. The method of claim 12, wherein the memory layer contains at least one of Co, Fe, Ni, and an alloy containing not less than two of Co, Fe, and Ni.

18. The method of claim 12, wherein the memory layer and the reference layer have in-plane magnetization.

19. The method of claim 12, wherein
the memory layer and the reference layer have perpendicular magnetization, and
the magnetoresistive element further includes a shift adjustment layer having an invariable magnetization direction opposite to the magnetization direction in the reference layer.

20. The method of claim 12, wherein the magnetoresistive element and the first interconnection are electrically connected via a current path of a transistor.
